(19) United States
(12) Patent Application Publication
(10) Pub. No.: US 2024/0243055 A1
(43) Pub. Date: Jul. 18, 2024

(54) ELECTRONIC-COMPONENT MOUNTING PACKAGE AND ELECTRONIC DEVICE

(71) Applicant: KYOCERA Corporation, Kyoto-shi, Kyoto (JP)

(72) Inventor: Toshihiko KITAMURA, Kyoto-shi (JP)

(73) Assignee: KYOCERA Corporation, Kyoto-shi, Kyoto (JP)

(21) Appl. No.: 18/557,765

(22) PCT Filed: Apr. 26, 2022
(86) PCT No.: PCT/JP2022/018814

§ 371 Date: Oct. 27, 2023

(30) Foreign Application Priority Data
Apr. 27, 2021 (JP) 2021-075129

(51) Int. Cl. H01L 23/498; H01L 23/057

(52) U.S. Cl. CPC H01L 23/49838; H01L 23/057

(57) ABSTRACT

An electronic-component mounting package includes: an insulating wiring laminate including an upper surface; differential lines located on the wiring laminate; differential lines located on the upper surface and alongside the differential lines and having shorter line lengths than the differential lines; and a wall covering part of each of the differential lines and being in contact with the upper surface of the wiring laminate. The wall includes a protruding portion in plan view from above the upper surface, and portions of the differential lines, the portions being covered with the protruding portion, are longer than portions of the differential lines, the portions being covered with the protruding portion.

### TECHNICAL FIELD

The present disclosure relates to an electronic-component mounting package and an electronic device.

### BACKGROUND OF INVENTION

Electronic-component mounting packages containing an electronic component and coupling the electronic component to an electrical circuit such as an external substrate are known. Since the distances between terminals for coupling to the outside are relatively large compared with the size of the electronic component, and as signal lines for coupling the electronic component to the outside extend from the portions coupled to the electronic component, the distances between the signal lines increase. Hence, the lengths of the signal lines differ from one another. This can cause phase differences between signals being transmitted in the signal lines.

To address this, Japanese Unexamined Patent Application Publication No. 2020-5018 discloses a technology in which a dielectric is located on an inner curved signal line at curved portions of two signal lines and decreases the signal transmission speed, thereby enabling adjustment of the phase difference, in other words, the electrical length.

### SUMMARY

### Solution to Problem

An aspect of the present disclosure is
an electronic-component mounting package including:
a first insulation layer including a first surface;
a first signal line located on the first surface;
a second signal line located on the first surface and alongside the first signal line and having a shorter line length than the first signal line; and
a second insulation layer covering part of the first signal line and part of the second signal line and being in contact with the first surface, in which
the second insulation layer includes a protruding portion in plan view from above the first surface, and
a portion of the second signal line, the portion being covered with the protruding portion, is longer than a portion of the first signal line, the portion being covered with the protruding portion.

### Advantageous Effect

The present disclosure enables the electrical lengths of a plurality of signal lines to be made uniform with higher accuracy.

### BRIEF DESCRIPTION OF THE DRAWINGS

FIG. 1 is a perspective view of a semiconductor electronic device illustrating its overall configuration.

FIG. 2 is a plan view of a semiconductor package from above.

FIG. 3A is an enlarged plan view of a protruding portion and its vicinity.

FIG. 3B is an enlarged perspective view of the protruding portion and its vicinity.

### DESCRIPTION OF EMBODIMENTS

Hereinafter, an embodiment will be described with reference to the drawings.

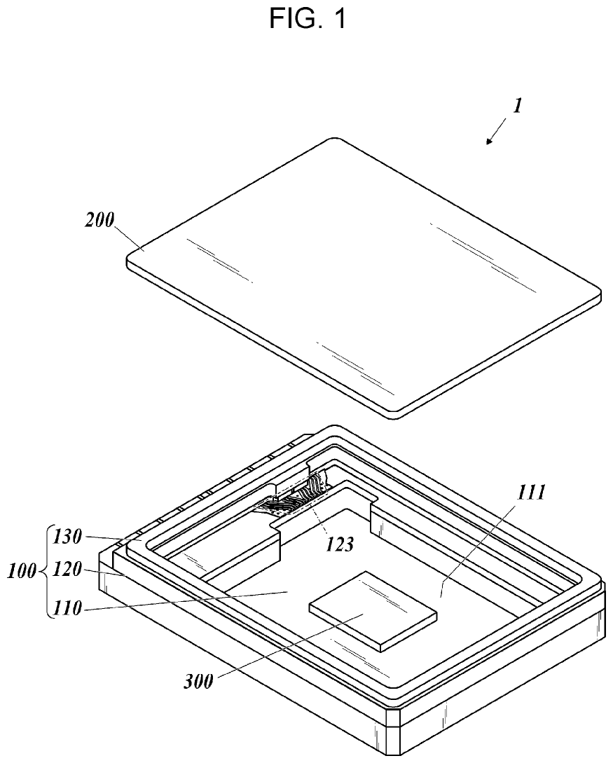

FIG. 1 is a perspective view of a semiconductor electronic device 1 of the present embodiment illustrating its overall configuration.

The semiconductor electronic device 1, which is an electronic device of the present embodiment, includes a semiconductor package 100, a lid 200, an electronic component 300, and the like. The semiconductor package 100, which is an electronic-component mounting package of the present embodiment, houses the electronic component 300. The semiconductor package 100 includes a substrate 110 including one surface (an upper surface 111) on which the electronic component 300 is located, a frame-shaped housing 120 extending along the edges of the upper surface 111 so as to surround the upper surface 111, and a frame 130 (a seal ring) and has a recessed shape having an opening on the upper side of the frame-shaped housing 120 opposite to the substrate 110 side (the lower side). The upper side is sealed with the lid 200, which is joined to the upper surface of the frame 130.

The frame-shaped housing 120 has signal lines 123, which are coupled to the electronic component 300 with bonding wires (not illustrated) or the like in the recess of the semiconductor package 100. The signal lines 123 couple the inside and the outside of the recess. The signal lines 123 contain, for example, a metal material such as gold, silver, copper, nickel, tungsten, molybdenum, and manganese, or a combination of some of these materials. The surfaces of the signal lines 123 may be additionally covered with nickel plating, gold plating, or the like. Such plating improves the corrosion resistance and the weather resistance of the signal lines 123 and also improves the wettability of a joining material, such as a brazing material or solder, which is joined to the plated surfaces.

The lid 200 is joined to the upper surface of the frame 130 so as to cover the recess of the semiconductor package 100. The lid 200 is a conductor which is, for example, a metal containing iron, copper, nickel, chromium, cobalt, molybdenum, or tungsten, or an alloy of some of these.

The electronic component 300 is located on the upper surface 111 and sits within the recess. The electronic component 300 is, for example, a semiconductor element such as an IC chip that transmits and receives signals through the bonding wires and the signal lines 123 described above.

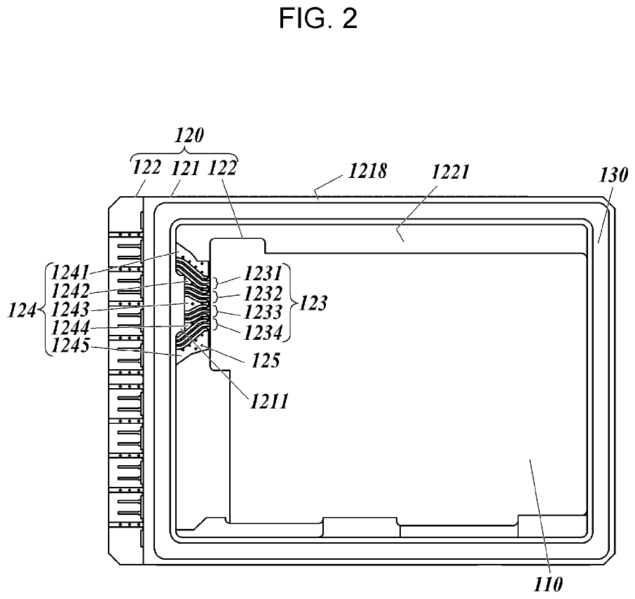

FIG. 2 is a plan view of the semiconductor package 100 from above.

The frame-shaped housing 120 includes a wall 121 (a second insulation layer) having a rectangular annular shape in plan view and a wiring laminate 122 (a first insulation layer) including an upper surface 1221 (a first surface) on which the signal lines 123 are located.

At least a portion of the upper surface 1221 of the wiring laminate 122, the portion overlapping the wall 121 in plan view, has a uniform height from the bottom face being in contact with the upper surface 111 of the substrate 110. The portions of the upper surface 1221 not overlapping the wall 121 in plan view may have a nonuniform height; specifically, they may have a structure including a plurality of steps.

The portion of the wall 121 overlapping the wiring laminate 122 in plan view is joined to the upper surface of the wiring laminate 122. Hence, part of each signal line 123 is covered with the wall 121. The wall 121 and the wiring laminate 122 may have an integrally formed structure or may be two structures formed separately and then joined.

The wall 121 is an insulation member such as a ceramic. The wall 121 is formed by defining its three-dimensional shape and may be, for example, a member obtained by preparing a slurry containing the powder of a material substance (for example, aluminum oxide, silicon oxide, and the like) mixed with an organic binder and a solvent, forming the slurry into sheets, laminating a plurality of insulation sheets (ceramic green sheets), and pressing and firing the laminate. If necessary, processing such as cutting and stamping may be added as appropriate. The wiring laminate 122 includes a plurality of insulation layers, and signal lines and/or a ground conductor surface (a second ground conductor) is located separately on each insulation layer.

The signal lines 123 located on the upper surface 1221 of the wiring laminate 122 are coupled on the outside of the area surrounded by the wall 121 to coupling terminals (not illustrated) for coupling to external portions. Here, the signal lines 123 include four pairs of differential lines 1231 to 1234, for eight lines in total, each pair including two lines located alongside each other. Ground conductors 1241 to 1245 (first ground conductors, also collectively referred to as ground conductors 124) are located on either side of each pair of differential lines 1231 to 1234. Each of the ground conductors 124 is coupled to a ground conductor located on another insulation layer via through conductors 125 (via hole conductors) extending through the insulation layers of the wiring laminate 122 in the up-down direction. Note that the number of pairs (the number of lines) of signal lines 123 (differential lines) in actual applications is not limited to this example. For manufacturing the wiring laminate 122, for example, a metal paste is prepared by mixing a conductor metal, a binder, and an organic solvent described above. When the insulation sheets described above are laminated, this metal paste is applied onto each insulation sheet by screen printing or the like. The insulation sheets on each of which the metal paste is printed are laminated together with plain insulation sheets and subjected to pressing and firing as described above.

The distances between the coupling terminals are sometimes defined in accordance with a specification and are thus larger than the distances between the signal lines 123 in the area surrounded by the frame-shaped housing 120, in other words, the distances between the signal lines 123 at the portions coupled to the electronic component 300. Accordingly, as the signal lines 123 extend from the inside to the outside of the frame-shaped housing 120, the distances between the signal lines 123 increase (the distances are not limited to increasing monotonically). For this reason, the lengths (the line lengths) of the differential lines 1232 and 1233 (the second signal lines) are shorter than the lengths (the line lengths) of the differential lines 1231 and 1234 (the first signal lines). The wall 121 includes a protruding portion 1211 located over these differential lines 1232 and 1233 and protruding inward of the semiconductor package 100 in plan view.

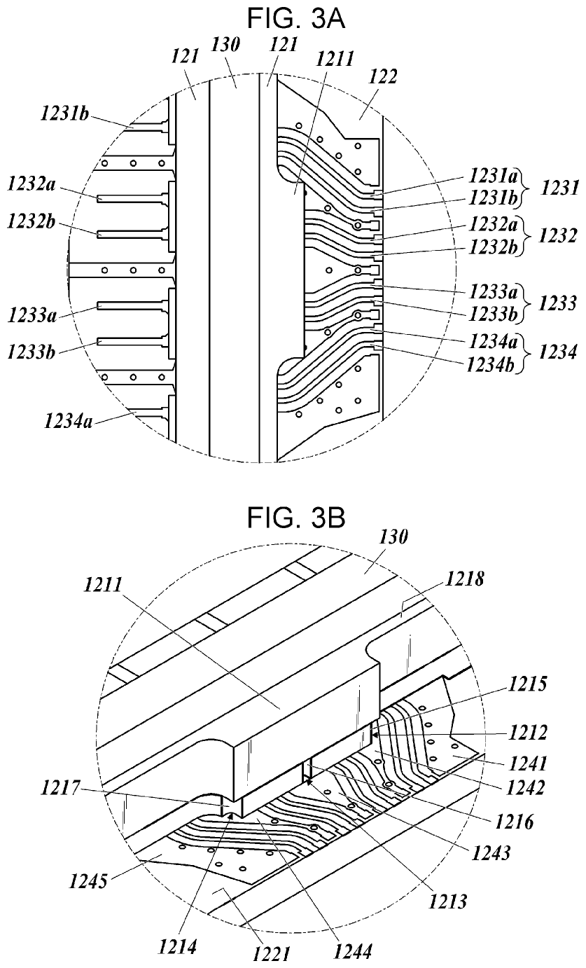

FIG. 3A is an enlarged plan view of the protruding portion 1211 and its vicinity, and FIG. 3B is an enlarged perspective view of the protruding portion 1211 and its vicinity.

The protruding portion 1211 is trapezoidal or rectangular. The trapezoidal or rectangular shape mentioned here is not limited to one with straight sides, as illustrated in FIG. 3A. For example, it includes a shape in which both sides in the extending direction (a direction perpendicular to the protruding direction) are curved to be recessed.

Of the two sides coupled to the one side located on top of the protruding portion 1211, one side is located on the ground conductor 1242 between the differential lines 1231 (signal lines 1231a and 1231b) and the differential lines 1232 (signal lines 1232a and 1232b), and the other side is located on the ground conductor 1244 between the differential lines 1233 (signal lines 1233a and 1233b) and the differential lines 1234 (signal lines 1234a and 1234b). Hence, of the differential lines 1231 to 1234, only the differential lines 1232 and 1233 are covered with the protruding portion 1211, and accordingly, the portions of the differential lines 1232 and 1233 covered with the wall 121 are longer than those of the differential lines 1231 and 1234. The signal lines 123 transmit signals substantially in a stripline structure in the portions between the insulation layer of the wiring laminate 122 and the insulation layer of the wall 121 and in a microstrip structure in the portions where the signal lines 123 are not covered with the wall 121. In the portions covered with the wall 121, the permittivity is larger than that of the portions not covered with the wall 121, and the signal transmission speed is lower. Thus, in the differential lines 1232 and 1233, the line lengths are shorter than those of the differential lines 1231 and 1234, but the signal transmission speed is lower, which increases the apparent electrical lengths of the differential lines 1232 and 1233. This decreases the phase difference between the differential lines 1231 and 1234 and the differential lines 1232 and 1233.

As illustrated in FIG. 3B, the protruding portion 1211 of the wall 121 includes recesses 1212 to 1214, one end of each being located at the lower surface and in contact with the wiring laminate 122. The inner surfaces of these recesses 1212 to 1214 are covered with conductors (coupling conductors 1215 to 1217), and each of these conductors is electrically coupled to the corresponding one of the ground conductors 1242 to 1244 on the upper surface 1221 of the wiring laminate 122. The recesses 1212 to 1214 are located lower than the upper surface of the protruding portion 1211 (the wall 121), in other words, the recesses 1212 to 1214 do not extend up to the upper surface. The upper ends of the coupling conductors 1215 to 1217 are coupled to a ground conductor inside the wiring laminate 122. Thus, the recesses 1212 to 1214 form castellations. Since the coupling conductors 1215 to 1217 do not extend up to the upper surface of the protruding portion 1211, the brazing material used when the frame 130 is joined to the wall 121 is less likely to flow down along the coupling conductors 1215 to 1217.

A conductor layer 1218 is located on the upper surface of the wall 121. This improves the joining strength between the conductor layer 1218 and the frame 130 joined with a brazing material.

The conductor layer 1218 and the conductors located on the upper surface 1221 of the wiring laminate 122 may be formed as a metalized layer by firing or may be formed by plating or the like, separately from the conductors inside the wiring laminate 122 described above.

The recesses 1212 to 1214 are located at the corners of the protruded area of the protruding portion 1211, which here are both ends of the one side being on top of the protrusion, and near the center of the one side. Since the recesses 1212 and 1214 are located at both ends of the protruded area, the protruding portion 1211 has a shape without corner edges. Hence, the paths of the differential lines 1231 and 1234 not covered with the protruding portion 1211 for detouring around the corners can be shorter, and the difference in the line lengths can be efficiently reduced while sufficient ground surface areas can be allocated.

As described above, the semiconductor package 100, which is the electronic-component mounting package of the present embodiment, includes the wiring laminate 122 (the first insulation layer) including the upper surface 1221, the differential lines 1231 and 1234 which are pairs of signal lines located the upper surface 1221, the differential lines 1232 and 1233 which are pairs of signal lines located on the upper surface 1221 and alongside the differential lines 1231 and 1234 and having shorter line lengths than the differential lines 1231 and 1234, and the wall 121 (the second insulation layer) covering parts of the differential lines 1231 to 1234 and being in contact with the upper surface 1221. The wall 121 has the protruding portion 1211 in plan view from above the upper surface 1221, and the portions of the differential lines 1232 and 1233 covered with the protruding portion 1211 are longer than those of the differential lines 1231 and 1234.

As described above, since the lengths of the portions covered with the wall 121 from above differ between the differential lines 1231 and 1234 and the differential lines 1232 and 1233 which have different lengths, the range where the signal transmission speed is lower differs. This enables the phase difference in the signals to be reduced. In addition, since the wall 121 having a layered structure is stacked on the upper surface 1221, the size, shape, and the like can be easily controlled. This improves the accuracy of adjustment of the phase difference. In addition, the wall 121 can be stably fixed, and the upper surface shape can be flattened with high accuracy. This enables the frame 130 to be joined onto the wall 121 more stably. Since the differential lines 1231 to 1234 couple the inside and the outside of the frame-shaped housing 120 in a single plane, the structure is not complex, and this enables easy and cost-effective manufacturing.

The protruding portion 1211 covers only the differential lines 1232 and 1233 of the differential lines 1231 and 1234 and the differential lines 1232 and 1233. With this configuration, the adjustment of the lengths of the signal lines 123 obliquely intersecting the wall 121 in plan view is performed only for the differential lines 1232 and 1233 by adjusting the protruding portion 1211, and hence the adjustment is simple. This makes it easy to achieve high accuracy.

These signal lines include pairs of two lines (the signal lines 1231a, 1232b, and the like) located alongside each other, the pairs serving as the differential lines 1231 to 1234. Since differential lines are more susceptible than other kinds of lines to the phase difference between signal lines, appropriate adjustment in the transmission speed as described above makes it possible to transmit signals while reducing the phase difference.

The semiconductor package 100 includes the ground conductors 1241 to 1245 located on either side of each pair of differential lines 1231 and 1234 and each pair of differential lines 1232 and 1233 on the upper surface 1221. The wall 121 includes a ground conductor inside, separately from the upper surface 1221. The protruding portion 1211 is rectangular or trapezoidal in plan view and includes the recesses 1212 and 1214 located at the corners of the protruded area of the protruding portion 1211 and overlapping the ground conductors 1242 and 1244. The inner surfaces of the recesses 1212 and 1214 have the coupling conductors 1215 and 1217 coupling the ground conductors 1242 and 1244 and the ground conductor inside the wall 121.

In the case in which the portion overlapping the protruding portion 1211 in plan view does not have via hole conductors for grounding, grounding is not sufficient. On the other hand, in the case in which the protruding portion 1211 has via hole conductors (via holes), the size of the protruding portion 1211 needs to be larger than the size necessary for the signal lines in view of strength and the like. Forming the castellations at the recesses 1212 and 1214 solves both problems because the castellations enhance the grounding and do not increase the size of the protruding portion 1211 more than necessary.

The method of forming the castellations is, for example, applying a conductor material to the portions of a ceramic green sheet that has been punched into the shape of the castellations. The insulation sheets having the castellations as above are stacked to form a specified shape of the wall 121 and subjected to firing.

The recesses 1212 and 1214 are located lower than the upper surface of the wall 121. In other words, the recesses 1212 and 1214 do not reach the upper surface of the wall 121. Since the upper surface of the wall 121 is to be joined to the frame 130 with a brazing material or the like, if the recesses 1212 and 1214 reach the upper surface, the brazing material is more likely to flow down along the coupling conductors 1215 and 1217 in the recesses 1212 and 1214. Since the recesses 1212 and 1214 are located lower than the upper surface of the wall 121, such flowing down can be avoided.

The conductor layer 1218 is located on the upper surface of the wall 121. This improves the joining strength between the frame-shaped housing 120 and the frame 130.

The semiconductor electronic device 1, which is the electronic device of the present embodiment, includes the semiconductor package 100 described above and the electronic component 300 coupled to the semiconductor package 100. The semiconductor electronic device 1 described above enables the electronic component 300 to be easily coupled to an external component, such as a flexible substrate or the like.

Note that the above embodiment is a mere example and hence can be changed in various ways.

For example, although the description of the above embodiment assumes that the differences in the lengths of the differential lines 1231 and 1234 and those of the differential lines 1232 and 1233 differ, the present disclosure includes a case in which the lengths of two signal lines (for example, the signal line 1231a and the signal line 1231b) differ from each other in each pair of the differential lines 1231 to 1234.

Although the description of the above embodiment assumes that the signal lines are differential lines, these signal lines are not limited to being differential lines.

Although the description of the above embodiment assumes that the differential lines 1231 and 1234 are not covered with the protruding portion 1211, line length portions of the differential lines 1231 and 1234 shorter than those of the differential lines 1232 and 1233 covered with the protruding portion 1211 may be covered with the protruding portion 1211.

Although the description of the above embodiment assumes that the protruding portion 1211 is trapezoidal or rectangular, the shape is not limited to this example. The protruding portion 1211 may be triangular, semicircular, arcuate, or of a shape similar to these.

Although the widths of the signal lines are not mentioned in the above embodiment, the widths of the signal lines may partially differ so that the characteristic impedances that change due to the difference between the stripline structure covered with the protruding portion 1211 and the microstrip structure can be appropriately adjusted. Specifically, the signal lines may be narrower in the portions covered with the wall 121 than in the other portions.

The signal lines are not limited to being straight in the area covered with the wall 121. The signal lines may be curved.

Although the description of the above embodiment assumes that the protruding portion 1211 includes the recesses 1212 and 1214 as castellations at the corners of the protruded area, the present disclosure is not limited to this example. Castellations may be formed only in the other portions, or the protruding portion 1211 may have only common via hole conductors or the like instead of castellations.

Although the description of the above embodiment assumes that the recesses 1212 and 1214 are located lower than the upper surface of the protruding portion 1211 (the wall 121), a configuration in which the recesses 1212 and 1214 reach the upper surface is possible.

Although the description of the above embodiment assumes that the lid 200 is a member separate from the semiconductor package 100, the lid 200 may be included in the semiconductor package 100.

Although the description of the above embodiment assumes that the electronic-component mounting package is the semiconductor package 100 on which a semiconductor element is mounted as the electronic component 300, the electronic component 300 is not limited to a semiconductor element. Any kind of electronic component may be mounted thereon.

The method of fabricating the semiconductor package 100 is not limited to one using insulation sheets as described above. The semiconductor package 100 may be fabricated by another method, for example, one using a 3D printer.

The semiconductor package 100 described above may be manufactured and sold separately from the electronic component 300. In this case, the lid 200 may be sold in a state of not being joined to the semiconductor package 100.

In addition, specific details of the configurations, materials, and structures illustrated in the above embodiment may be changed as appropriate within a scope not departing from the spirit of the present disclosure. The scope of the present invention includes the scope of the claims and the equivalents thereof.

### INDUSTRIAL APPLICABILITY

The present disclosure can be used for an electronic-component mounting package and an electronic device.

1. An electronic-component mounting package comprising:
a first insulation layer comprising a first surface;
a first signal line located on the first surface;
a second signal line located on the first surface and alongside the first signal line and having a shorter line length than the first signal line; and
a second insulation layer covering part of the first signal line and part of the second signal line and being in contact with the first surface, wherein
the second insulation layer comprises a protruding portion in plan view from above the first surface, and
a portion of the second signal line, the portion being covered with the protruding portion, is longer than a portion of the first signal line, the portion being covered with the protruding portion.

2. The electronic-component mounting package according to claim 1, wherein
the protruding portion covers only the second signal line of the first and second signal lines.

3. The electronic-component mounting package according to claim 1, wherein
each of the first signal line and the second signal line comprises two differential lines located alongside each other.

4. The electronic-component mounting package according to claim 1, further comprising
a first ground conductor located on the first surface and on both sides of each of the first signal line and the second signal line, wherein
the second insulation layer comprises a second ground conductor located separately from the first surface,
the protruding portion is rectangular or trapezoidal in plan view and comprises recesses at corners of a protruded area of the protruding portion, the recesses overlapping the first ground conductors, and
an inner surface of each recess comprises a coupling conductor coupling the first ground conductor and the second ground conductor to each other.

5. The electronic-component mounting package according to claim 4, wherein
the recesses are located lower than an upper surface of the second insulation layer.

6. The electronic-component mounting package according to claim 1, wherein
a conductor layer is located on an upper surface of the second insulation layer.

7. An electronic device comprising:
the electronic-component mounting package according to claim 1; and
an electronic component coupled to the electronic-component mounting package.
